(19) United States
(12) Patent Application Publication
(10) Pub. No.: US 2007/0066085 A1
(43) Pub. Date: Mar. 22, 2007

(54) METHOD OF FABRICATING DIELECTRIC LAYER

(76) Inventors: Hsien-Che Teng, Tainan City (TW); June-Hung Wu, Kaohsiung County (TW); Jin-Fu Lin, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,726

(22) Filed: Sep. 21, 2005

(51) Int. Cl. H01L 21/469

(52) U.S. Cl. 438/778; 438/798

(57) ABSTRACT

A method of fabricating a dielectric layer is described. A twelve-inch wafer having at least three metallic layers thereon is provided. A dielectric layer is formed over the twelve-inch wafer by performing a high-density plasma process. The high-density plasma process includes applying a total bias radio frequency (RF) power and a total source radio frequency (RF) power. Furthermore, the ratio between the total bias RF power and the total source RF power is about 0.7 to 2.5.

### BACKGROUND OF THE INVENTION

1. Field of the Invention

The present invention relates to a method of fabricating a semiconductor device. More particularly, the present invention relates to a method of fabricating a dielectric layer.

2. Description of the Related Art

With the rapid development in the semiconductor fabrication industry, the design of integrated circuits in increasingly precise and complicated. To boost the performance and operating speed of electronic products further, the number of devices per unit area is increased so that the surface of a wafer can hardly provide sufficient area for fabricating interconnects. In order to meet the increase in interconnecting lines resulting from device miniaturization, some of the functionally sophisticated products need to have five of more metallic layers. Because a metallic layer typically has a higher tensile stress than surrounding non-metallic material, an increase in the number of metallic layers in a wafer often leads to an increase in overall tensile stress. Hence, the degree of warpage in a wafer is increased as shown in FIG. 1. As shown in FIG. 1, the curvature 103 of the wafer 101 is defined as the maximum distance between the surface of the wafer 101 and a horizontal line from one edge of the wafer 101 to a diametrically opposite edge. Under a normal condition when the wafer 101 is not subjected to any tension, the surface of the wafer 101 should be flat. However, as the wafer 101 is subjected to increasing tensile stress, the curvature 103 grows bigger.

With the diameter of silicon wafer increasing from eight-inch in the past to twelve-inch, the problem of having a warped wafer is more prominent. Once the warpage is greater than 400 μm, the photo-exposure of wafer in a photolithographic process on a plane surface can no longer be guaranteed. Thus, the transferred pattern after the photolithographic process may be significantly altered. In serious cases, the entire batch of silicon wafers may have to be scrapped.

### SUMMARY OF THE INVENTION

Accordingly, at least one objective of the present invention is to provide a method of fabricating a dielectric layer capable of increasing the compressive stress of the dielectric layer so that the problems of having a warped wafer and an improper transfer of pattern after a photolithographic process are minimized.

To achieve these and other advantages and in accordance with the purpose of the invention, as embodied and broadly described herein, the invention provides a method of fabricating a dielectric layer. First, a twelve-inch wafer having at least three metallic layers thereon is provided. A dielectric layer is formed over the twelve-inch wafer by performing a high-density plasma process. The high-density plasma (HDP) process includes applying a total bias radio frequency (RF) power and a total source radio frequency (RF) power. Furthermore, the ratio between the total bias RF power and the total source RF power is between about 0.7 to 2.5.

According to one preferred embodiment of the present invention, the metallic layer is fabricated using aluminum or copper.

According to one preferred embodiment of the present invention, the metallic layer comprises a plurality of coplanar metallic sections.

According to one preferred embodiment of the present invention, the length of each metallic section does not exceed 250 μm.

According to one preferred embodiment of the present invention, the compressive stress of the dielectric layer is higher than 8*E⁸ dyne/cm².

The present invention also provides an alternative method of fabricating a dielectric layer suitable for operating inside a high-density plasma processing station. The high-density plasma processing station comprises a wafer carrier and a reaction chamber. The method of fabricating the dielectric layer includes providing a twelve-inch wafer and putting the twelve-inch wafer on the wafer carrier. The twelve-inch wafer has at least three metallic layers thereon and each metallic layer has a plurality of coplanar metallic sections with each metallic section having a length not exceeding 250 μm. Thereafter, a high-density plasma (HDP) processing is performed to form a dielectric layer over the twelve-inch wafer.

According to one preferred embodiment of the present invention, the high-density plasma processing in the method of fabricating the dielectric layer includes applying a total bias radio frequency (RF) power and a total source radio frequency (RF) power to the wafer. The ratio between the total bias RF power and the total source RF power is between about 0.7 to 2.5.

According to one preferred embodiment of the present invention, the metallic layer is fabricated using aluminum.

According to one preferred embodiment of the present invention, the compressive stress of the dielectric layer is higher than 8*E⁸ dyne/cm².

In the present invention, a high-density plasma processing is performed by applying total bias RF power and total source RF power with a ratio between the two of between about 0.7 to 2.5. Therefore, the compressive stress of the dielectric layer is increased and the degree of warping in the wafer is improved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view showing the warpage in a conventional wafer.

FIG. 2 is a schematic cross-sectional view of an apparatus for fabricating a dielectric layer according to one preferred embodiment of the present invention.

FIG. 3 is a flow chart showing the steps for fabricating a dielectric layer over a wafer according to one preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

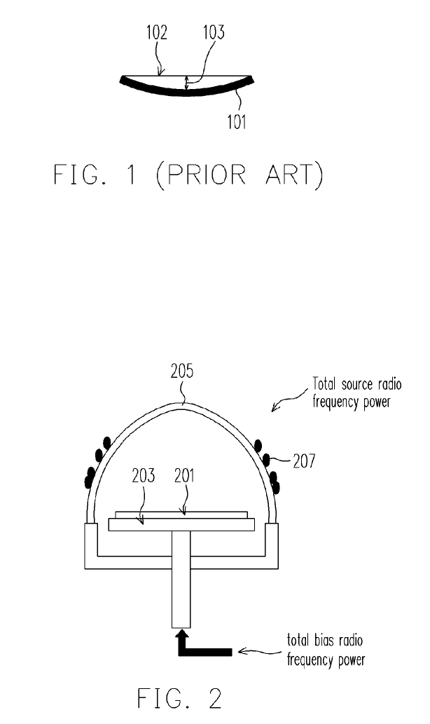

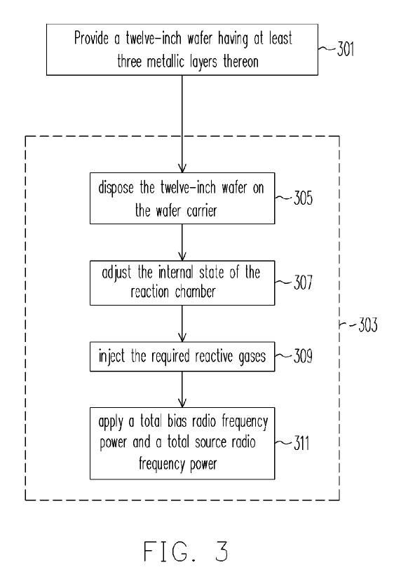

FIG. 2 is a schematic cross-sectional view of an apparatus for fabricating a dielectric layer according to one preferred embodiment of the present invention. FIG. 3 is a flow chart showing the steps for fabricating a dielectric layer over a wafer according to one preferred embodiment of the present invention. As shown in FIGS. 2 and 3, the present invention provides a method of fabricating a dielectric layer over a wafer. First, a twelve-inch wafer 201 having at least three metallic layers (not shown) formed thereon (in step 301) is provided. The metallic layers are aluminum layers or copper layers formed, for example, by performing physical vapor deposition, a chemical vapor deposition process or some other suitable processes. In one preferred embodiment, each metallic layer may comprise a plurality of coplanar metallic sections. In another preferred embodiment, the maximum length of each metallic section does not exceed 250 μm.

Thereafter, a high-density plasma process is carried out to form a dielectric layer (not shown) (in step 303) over the twelve-inch wafer 201. In one embodiment, the station 100 for performing the high-density plasma process comprises a wafer carrier 203 and a reaction chamber 205. The reaction chamber 205 can have a inductive coupled plasma (ICP), an electron cyclotron resonance (ECR) or some other suitable design.

The twelve-inch wafer 201 is placed on the wafer carrier 203 (in step 305). Thereafter, the internal states of the reaction chamber 205 are adjusted. For example, the pressure inside the reaction chamber 205 is reduced, various setups within the reaction chamber 205 are initialized or any unwanted gases inside the reaction chamber 205 are removed. After that, reactive gases need for material deposition is injected into the reaction chamber 205 (in step 309). To deposit a silicon oxide film, reactive gases such as silane (SiH₄) and oxygen (O₂) are pumped into the reaction chamber 205.

In carrying out the high-density plasma process, a total bias radio frequency (RF) power and a total source radio frequency (RF) power are applied (in step 311). The total bias RF power and the total source RF power can be applied by several power supplies and the values of the total bias RF power and the total source RF power are the sum of the individual power supply respectively. The total source RF power is applied through a radio frequency (RF) coil 207 disposed on the outer wall of the reaction chamber 205 while the total bias RF power is applied through the wafer carrier 203 inside the reaction chamber 205. Furthermore, the ratio between the total bias RF power and the total source RF power is about 0.7 to 2.5. Since the dielectric layer formed in the present embodiment has a compressive stress greater than 8*E⁸ dyne/cm², some of the tensile stress in the metallic layers can be canceled to improve the warping problem in the twelve-inch wafer 201.

In the present invention, a high-density plasma processing is performed by applying a total bias RF power and a total source RF power with a ratio between the two of between about 0.7 to 2.5. Therefore, the compressive stress of the dielectric layer is increased and a portion of the tensile stress created by the metallic layers within the wafer is canceled. In addition, the tensile stress within the wafer is also reduced by limiting the length of the metallic sections in each metallic layer below 250 μm. Ultimately, the degree of warping in the wafer is improved. Hence, pattern on a photomask can be properly transferred to a wafer after a subsequent photo-exposure in a photolithographic process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a dielectric layer, comprising the steps of:
providing a twelve-inch wafer, wherein the twelve-inch wafer has at least three metallic layers; and
performing a high-density plasma process to form a dielectric layer over the twelve-inch wafer, wherein the high-density plasma process includes applying a total bias radio frequency (RF) power and a total source radio frequency (RF) power such that the ratio of the total bias RF power to the total source RF power falls between 0.7 to 2.5.

2. The method of claim 1, wherein the material constituting the metallic layers comprises aluminum or copper.

3. The method of claim 1, wherein each metallic layer comprises a plurality of coplanar metallic sections.

4. The method of claim 3, wherein the metallic sections has a length not exceeding 250 μm.

5. The method of claim 1, wherein the compressive stress in the dielectric layer is higher than 8*E⁸ dyne/cm².

6. A method of fabricating a dielectric layer that can be applied to a high-density plasma processing station, wherein the high-density plasma processing station comprises a wafer carrier and a reaction chamber, the method comprising the steps of:
providing a twelve-inch wafer, wherein the twelve-inch wafer is placed on the wafer carrier, the twelve-inch wafer has at least three metallic layers thereon such that each metallic layer comprises a plurality of coplanar metallic sections with each metallic section having a length not exceeding 250 μm; and
performing a high-density plasma process to form a dielectric layer over the twelve-inch wafer.

7. The method of claim 6, wherein the a total source radio frequency (RF) power is applied over the reaction chamber and a total bias radio frequency (RF) power is applied to the wafer carrier such that the ratio of the total bias RF power to the total source RF power is between about 0.7 to 2.5.

8. The method of claim 6, wherein the material constituting the metallic layers comprises aluminum or copper.

9. The method of claim 6, wherein the compressive stress of the dielectric layer is higher than 8*E⁸ dyne/cm².
